(19) United States
(12) Patent Application Publication
(10) Pub. No.: US 2005/0042422 A1
(43) Pub. Date: Feb. 24, 2005

(54) Point attachment systems for laminated glass

(76) Inventors: Stephen J. Bennison, Wilmington, DE (US); Charles Anthony Smith, Vienna, WV (US); James G. Sloan, Newark, DE (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 10/868,305

(22) Filed: Jun. 14, 2004

Related U.S. Application Data
(60) Provisional application No. 60/478,395, filed on Jun. 13, 2003.

(30) Foreign Application Priority Data
Jul. 31, 2003 (WO) PCT/US03/24118

(51) Int. Cl. B32B 3/10; H01L 21/4763

(52) U.S. Cl. 428/137

(57) ABSTRACT

The present invention is a direct-point attachment laminate system comprising: (1) a thermoplastic interlayer; (2) at least one sheet of a rigid structural load-bearing layer (structural layer); (3) at least one receptor means; and (4) at least one attachment means, wherein the thermoplastic interlayer is bonded on at least one surface to at least one sheet of the structural layer, and wherein at least one receptor means is also adhesively bonded to the thermoplastic interlayer and thereby adhesively bonded to the structural layer, wherein the receptor means is positioned to mechanically accept the attachment means, with the further proviso that the attachment means and/or the receptor means are made from materials having a coefficient of expansion that is from about 90% to about 110% of the coefficient of expansion of the structural layer.

This Application claims the benefit of PCT Application No. PCT/US03/24118, filed Jul. 31, 2003 which claims the benefit of U.S. Provisional Application Ser. No. 60/400,234 filed Jul. 31, 2002.

### BACKGROUND OF THE INVENTION

Laminated glass can be useful in homes and buildings; shelving in cabinets and display cases; and other articles where structural strength and improved safety performance is desirable in glass. In architecture, there can be advantages in attaching glass to frames and building support structures by means of direct point-support systems that employ bolts and/or other non-adhesive fasteners. For example, bolted glazing systems allow for the design of minimal, highly transparent facades. In automotive applications, there is a desire to affix glazings in a vehicle to provide structural integrity, ease of installation/replacement and to create moveable glazings for access, egress, or ventilation purposes and the like.

Producing glazing systems that can be fastened to support structures via direct-point attachment (hereinafter “bolted glass”) is not trouble free. Using bolted glass systems can be difficult due to various factors inherent in a conventional bolted glass process. For example, bolted glass systems require the use of tempered glass which can lead to reduced optical clarity. Also, the one glass-ply and polymer interlayer are often treated as a redundant structural component.

Conventional laminated safety glass generally comprises thermoplastic sheeting laid between sheets of glass or other transparent plastic materials. These laminated glass composites are required to perform to stringent requirements including impact performance, weatherability, and transparency. However, the presence of the interlayer can also cause difficulties when using bolted glass. Interlayer creep can occur due to clamping forces of the point attachment to the support structure. Another concern when using bolted glass laminates is keeping the holes of the interlayer aligned with the holes in the glass during the lamination process. There are still further problems that can occur with conventional bolted glass systems relative to the compatibility between the interlayer and the fastener, and also the durability of the attachment.

One such other problem is that stress factors can build up in a glass laminate as a result of differences in the physical properties of the materials used to construct a laminate. In structural laminates that are contemplated for use in supporting other objects, stresses can lead to failure of the laminate as an architectural support structure either during fabrication of the laminate or when used in the intended application.

It can be desirable to have a bolted glass laminate that can overcome the problems of a conventional bolted glass system.

### BRIEF DESCRIPTION OF THE DRAWINGS

FIG. 1 is a drawing of the laminate showing the insert.

FIG. 2 is a drawing of the laminate in FIG. 1 with the top layers removed to show the insert with more clarity.

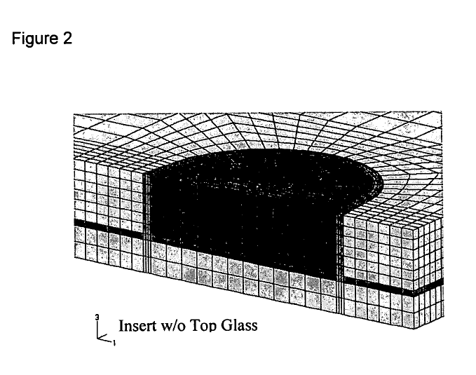

### SUMMARY OF THE INVENTION

In one aspect, the present invention is a direct-point attachment laminate system comprising: (1) a thermoplastic interlayer; (2) at least one sheet of a rigid structural load-bearing layer (structural layer); (3) at least one receptor means; and (4) at least one attachment means, wherein the thermoplastic interlayer is bonded on at least one surface to at least one sheet of the structural layer, and wherein at least one receptor means is also adhesively bonded to the thermoplastic interlayer and thereby adhesively bonded to the structural layer, wherein the receptor means is positioned to mechanically accept the attachment means, with the further proviso that the attachment means and/or the receptor means are made from materials having a coefficient of expansion that is from about 90% to about 110% of the coefficient of expansion of the structural layer.

In another aspect the present invention is a process for fabricating a glazing system suitable for direct-point attachment to a support structure comprising the steps: assembling a laminate comprising (1) a thermoplastic interlayer; (2) at least one sheet of a rigid structural load-bearing layer (structural layer); (3) at least one receptor means; and (4) at least one attachment means, wherein the thermoplastic interlayer is bonded on at least one surface to at least one sheet of the structural layer, and wherein at least one receptor means is also adhesively bonded to the thermoplastic interlayer and thereby adhesively bonded to the structural layer, wherein the receptor means is positioned to mechanically accept the attachment means, with the further proviso that the attachment means and/or the receptor means are made from materials having a coefficient of expansion that is from about 90% to about 110% of the coefficient of expansion of the structural layer.

In another aspect of the invention, the present invention is a process for fabricating a laminated glass load-bearing structural system that is suitable for a direct point attachment to a support structure via an attachment means and a receptor means comprising the step of choosing materials of construction for the laminate such that the attachment means and/or the receptor means have a coefficient of expansion that is within a range of from about 90% to about 110% of the coefficient of expansion of the glass.

### DETAILED DESCRIPTION

In one embodiment, the present invention is a load-bearing support system comprising a thermoplastic interlayer interspersed between at least two plies of a rigid structural support. The rigid support structure can be plastic, metal, wood, stone, or glass. Preferably, the support structure is rigid plastic or glass, and most preferably the rigid support structure is glass. In a particularly preferred embodiment, the glass is transparent to most wavelengths of light in the visible spectrum. In another preferred embodiment, the glass or interlayer can be colored or have a decorative image printed thereupon. The load-bearing support system can be attached to a support structure via a direct-point attachment, wherein the direct point attachment comprises a receptor for accepting an attachment means, said receptor being embedded in the interlayer in such a manner as to accept the attachment means. In the practice of the present invention, the load-bearing support system can be attached to the support structure and supported by the support structure via the attachment means being accepted by the receptor.

A support structure for the purposes of the present invention can be a building, a wall, a panel, a ceiling, a floor, a staircase, suspension wires, or any building structure or substructure having a load-bearing function. For the purposes of the present invention, windows are not considered load-bearing structures because they are not required to support additional load than what is placed on them when they are placed in a frame.

A load-bearing system for the purposes of the present invention can be: a floor or ceiling, stair-steps, a table, chairs, a desk, a column, a foundation for a display, or anything that can function in a load-bearing capacity.

A suitable attachment means can be any means for attaching the laminate to a support structure. Suitable attachment means can be, for example, at least one: bolt; metal pin, clamp; nail; screw; rope; chain; tether; snap; clip; or any combination of these. The important consideration is that the attachment means is suitable, that is can provide adequate support and strength, for the intended load-bearing application.

A suitable receptor means can be any feature that works together with an attachment means to create an attachment between a glazing system and a support structure. A suitable receptor means can be constructed of any material that is generally considered to be sturdy, such as for example: metals such as steel, aluminum, titanium, brass, lead, chrome, copper, and the like; plastics such as polycarbonate, polyvinyl butyral, polyurethane, nylon, poly(alkyl)acrylates, and the like; natural materials such as stone, wood, or the like, or composite materials obtained from suitable materials as described herein. The proviso being that the receptor must be a material that can bond with the polymeric material used as the interlayer and/or to line a cavity or recessed area that holds the receptor means, and have a coefficient of expansion that is compatible with the other materials used in the laminate, as described herein.

A suitable thermoplastic interlayer can be any that can form an adhesive bond with glass and also with the material of construction used to form the receptor for the attachment means. A suitable thermoplastic interlayer can be any interlayer that has the required adhesion to glass and to the attachment and/or receptor, such that the laminate can perform as intended in an architectural or engineering application. For example, a suitable interlayer can be obtained from an acid copolymer formed by copolymerization of an ethylenically unsaturated carboxylic acid or derivative thereof with ethylene. Derivatives of carboxylic acids are well known, but a preferred derivative can be an ionomeric polymer formed by full or partial neutralization of an acid copolymer suitable for use herein. Suitable acid copolymers or ionomers can be purchased commercially from E.I. DuPont de Nemours and Company under the tradenames Surlyn® and/or Nucrel®, for example. Other suitable thermoplastic interlayers can be, for example, “stiff” polyvinyl butyral (PVB) having a low level of plasticization (less than 30 pph parts of plasticizer), ethylene vinyl acetate (EVA), polyesters such as polyethylene terephthalate (PET), or polyurethane. Multilayer laminates comprising different combinations of interlayers (composite interlayers) are contemplated as within the scope of the present invention.

An interlayer of the present invention can be any thickness that can result in a structurally sound laminate when used for the purposes described herein. The thickness may in fact depend on the use intended for the laminate structure. The appropriate thickness can be readily determined for any given application. For the present purposes, the interlayer or interlayer composite of the present invention can have a thickness of anywhere in the range of from about 0.150 mm to about 20 mm. The interlayer can have a thickness, depending on the intended application or use of the glazing, of at least about 0.200 mm. In yet another application or use the interlayer can be at least about 0.250 mm or multiples thereof, or at least about 1 mm or multiples thereof, or at least about 1.33 mm or multiples thereof. In some other applications it may be appropriate to specify an interlayer thickness of as great as 10, 11, 12, 13 or 15 mm. The thickness of interlayer used can be determined by other factors such as cost or commercial availability.

The laminate can be fabricated according to known and conventional glass lamination techniques, with the exception that the laminate must have holes that will accept the receptor and attachment means, and the thermoplastic interlayer must form an adhesive bond with the glass surfaces and also the receptor in such a manner that the interlayer, the receptor, and the glass surfaces are joined with a suitable adhesive force.

In the practice of the present invention, it can be preferred to put the laminate into a load-bearing application such as a shelf; a floor; a ceiling; a stair tread or stair-step; a staircase; furniture such as a table, chair, or bookcase; a stand for an appliance; a stand for stereo equipment or a television; and/or similar applications. Other uses can include, for example, balustrades, sloped and curtain wall glazing constructs, automotive sidelites, automotive sun roofs and/or moon roofs. In such applications stresses that are inherent in the laminate may result in premature cracking or failure in the glass when a load is brought to bear on the laminate.

In the present invention, a process for substantially reducing or minimizing the occurrence of stress cracking in a load-bearing glass laminate is provided, wherein the internal stresses in the laminate are significantly reduced by appropriate choice of the materials of construction. It has been discovered that internal stresses in the laminates of the present invention can be substantially reduced by matching the material used to make the attachment means and/or receptor means so that it has a coefficient of expansion similar to the glass that is used in the laminate. Matching the materials of construction in the manner described herein thereby provides a laminate having improved stability during the fabrication process and also under load stress. The attachment means and/or the receptor means should be selected such that the coefficient of expansion of the material selected (CTEₘ) is from about 90% to about 110% of the coefficient of expansion for the glass (CTE_{g}) used to make the laminate. Preferably, CTEₘ is from about 92% to about 108% of CTE_{g}, more preferably from about 94% to about 106% of CTE_{g}, most preferably from about 95% to about 105% of CTE_{g}.

In a particularly preferred embodiment, the attachment means and/or the receptor means comprises materials such as: metals; plastics such as polycarbonate, polyvinyl butyral, polyurethane, nylon, poly(alkyl)acrylates, and the like; natural materials such as stone, wood, or the like. More preferred as materials of construction for the attachment means and/or receptor means are metals selected from the group consisting of steel, aluminum, titanium, brass, lead, chrome, copper, and the like. The material is selected such that it has a coefficient of linear expansion which is relatively close to the coefficient of expansion of the glass used in the laminate.

It is critical to the present invention that coefficient of expansion for glass be appropriately matched with the coefficient of expansion for the attachment and receptor means in order to obtain the improvement described herein. Conventional methods for determining coefficient of expansion of the materials used in the practice of the present invention may by used, or alternatively the values can be readily ascertained from tabulations of properties for the materials.

The thickness of the glass can also vary depending on the application and use that is intended for the laminate. The thickness of the glass for used contemplated herein can be any that results in a laminate that satisfies the intended purpose of the laminate, with the proviso that a glass sheet thickness that lies between a minimum thickness (which may be desirable due to cost considerations) and a maximum thickness (which may be desirable due to concerns about the laminate strength) can be desirable. It is expected that the thickness of a glass sheet useful herein would be at least 0.25 mm thick.

In another embodiment of the present invention, the materials of construction used for the attachment means and/or the receptor means can be matched to the glass such that the CTE at constant pressure for the attachment means and/or the receptor means (CTEₘ) is from about 95% to about 105% of the CTE of glass at constant pressure (CTE_{g}). Preferably CTEₘ is from about 96% to about 104% of CTE_{g}, more preferably from about 97% to about 103%, and most preferably from about 98% to about 102%.

### EXAMPLES

The following Examples and comparative examples are presented to further illustrate the present invention. The Examples are not intended to limit the scope of the invention in any manner, nor should they be used to define the claims or specification in any manner that is inconsistent with the invention as claimed and/or as described herein.

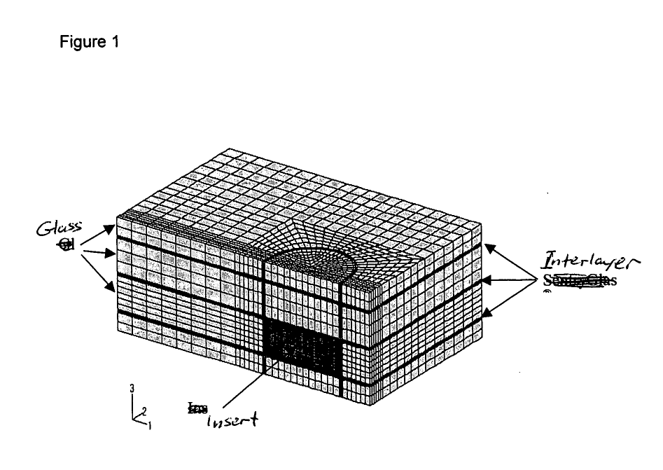

The following examples show results from finite element simulations of stress development in various attachment systems. They show that system internal residual stresses may be minimized by suitable choice of metal insert type and the interlayer thickness. FIG. 1 shows the insert detail and finite element model used.

### Example 1

The insert is fabricated from a 304 stainless steel and a 0.76 mm SentryGlas® Plus polymer interlayer shim is used. Table 1 shows the predicted system residual stress development after cooling from the fabrication temperature.

### Example 2

The insert is fabricated from a titanium alloy and a 0.76 mm SentryGlas® Plus polymer interlayer shim is used. Table 1 shows the predicted system residual stress development after cooling from the fabrication temperature. Note this example is predicted to show the minimum system residual stresses.

### Example 3

The insert is fabricated from a 17-4 PH stainless steel and a 2.29 mm SentryGlas® Plus polymer interlayer shim is used. Table 1 shows the predicted system residual stress development after cooling from the fabrication temperature.

### Example 4

The insert is fabricated from a titanium alloy and a 2.29 mm SentryGlas® Plus polymer interlayer shim is used. Table 1 shows the predicted system residual stress development after cooling from the fabrication temperature.

### Example 5

The insert is fabricated from a 17-4 PH stainless steel and a 0.76 mm SentryGlas® Plus polymer interlayer shim is used. Table 1 shows the predicted system residual stress development after cooling from the fabrication temperature.

### Example 6

Glass laminates can be prepared by the following method. Sheets of tempered glass 3000 mm×200 mm×6 mm thickness can be washed with a solution of trisodium phosphate (5 gms./liter) in deionized water, rinsed thoroughly with deionized water, and dried. One sheet of glass can be laid flat, or alternatively in any position that can facilitate fabrication of the laminate. A sheet (0.76 mm thick) of ionomer resin composed of 81% ethylene, 19% methacrylic acid, 37% neutralized with sodium ion and having a melt index (MI) of 2 can be placed on the exposed surface of the glass. The moisture level of said ionomer sheet should be below 0.06% by weight. The ionomer sheet can have a surface roughness via an embossing technique to allow for ease of air removal from between each assembled interface. A second piece of glass is placed over the ionomer sheet and a second piece of ionomer resin (which can either be the same as or different from the first ionomer sheet) is placed on the second sheet of glass. A third piece of glass is then placed over the second ionomer sheet, the second and third glass sheets having a recessed area to allow an insert to fit within the laminate assembly. Next a third ionomer sheet, which can be the same as or different from the other ionomer sheets, is placed over the third glass sheet and a fourth glass sheet is placed on top of the third ionomer sheet to yield a laminate assembly having alternating glass/ionomer sheets, wherein the inner glass sheets form a recessed area suitable for accepting a metal insert. Additional ionomer material can be placed within the recessed area to allow a ‘mechanical’ connection between the insert and ionomer to complete the laminate preassembly. The insert is a suitable material having the proper coefficient of thermal expansion as in the subject of this patent art. For example, titanium metal can be used as an insert material. The preassembly can be taped together with a piece of polyester tape to maintain the relative positioning of each layer. A nylon fabric strip can be placed around the periphery of the preassembly to facilitate air removal from within the layers. The preassembly can then be placed inside a nylon vacuum bag with a connection to a vacuum pump. A vacuum can be applied to allow substantial removal of air from within (air pressure inside the bag can be reduced to below 50 millibar absolute). The laminate preassembly can then be placed into an air autoclave and the pressure and temperature can be increased from ambient to 135° C. and 200 psi over a period of 15 minutes. This temperature and pressure should then be held for a sufficient period of time to allow the laminate assembly to heat properly (30 to 120 minutes could be typical). Next the temperature is decreased to 40° C. within a 20-minute period whereby the pressure is then dropped back to ambient and the unit is removed. The laminate assembly can then be mechanically tested in a high load-bearing applications, such as would be needed or considered beneficial for stair steps, floor tile unit, overhead, balustrades, sloped and curtainwall glazing constructs and the like.

For the Examples above the following are the Coefficient of Thermal Expansion (CTE) for the materials used:

| Material | CTE |
|---|---|
| Glass | 9.0 ppm |
| 304 Stainless Steel | 16.4 ppm |
| Titanium | 9.0 ppm |
| 17-4 | 11.7 ppm |

### Example 7

Laminates (55 mm×80 mm) were prepared by the preparation method outlined in Example 1 using a mild steel insert, 80 mm in length, 20 mm in width and 0.6 mm in thickness. A section of the steel was laminated within the area described by the two outer plies of glass measuring 20 mm in depth by 20 mm in width. The same metal insert was laminated on the opposing side of the laminate thus allowing the ability to place the metal tabs into a tensile testing apparatus (Instron*) and a conventional-like tensile test run otherwise according to that prescribed in ASTM D638. In this way, the force required to pull the insert from within the laminate construct could be evaluated. The failure mode in this case was metal fracture of the tab external to the laminate. The insert remained completely intact within the laminate without any apparent visible damage, distortion, delamination, or separation occurring between the metal insert and the surrounding ionomer material.

| Laminate ‘Mounting’ Method | Pullout force (max.) |
|---|---|
| Simple gasket (slot/support | 18 N (4 pounds) |
| shelf) | |
| Metal insert | 965 N (217 pounds) |

1. A direct-point attachment laminate system comprising: (1) a thermoplastic interlayer; (2) at least one sheet of a rigid structural load-bearing layer (structural layer); (3) at least one receptor means; and (4) at least one attachment means, wherein the thermoplastic interlayer is bonded on at least one surface to at least one sheet of the structural layer, and wherein at least one receptor means is also adhesively bonded to the thermoplastic interlayer and thereby adhesively bonded to the structural layer, wherein the receptor means is positioned to mechanically accept the attachment means, with the further proviso that the attachment means and/or the receptor means are made from materials having a coefficient of expansion that is from about 90% to about 110% of the coefficient of expansion of the structural layer.

2. The laminate system of claim 1 wherein the thermoplastic interlayer is a copolymer obtained by copolymerization of ethylene with an ethylenically unsaturated carboxylic acid or derivative thereof.

3. The laminate system of claim 2 wherein the interlayer has a thickness of from about 0.30 mm to about 1.5 mm.

4. The laminate system of claim 3 wherein each glass sheet has a thickness of at least about 0.25 mm.

5. The laminate system of claim 4 wherein the laminate comprises at least two sheets of glass.

6. The laminate system of claim 5 wherein each glass sheet has a coefficient of expansion in the range of from about 5 ppm to about 10 ppm per ° C.

7. The laminate system of claim 6 wherein the attachment means and/or the receptor means are made from materials having a coefficient of expansion that is from about 92% to about 108% of the coefficient of expansion of the glass.

8. The laminate system of claim 7 wherein the attachment means and/or the receptor means are made from materials having a coefficient of expansion that is from about 94% to about 106% of the coefficient of expansion of the glass.

9. The laminate system of claim 8 wherein the attachment means and/or the receptor means are made from materials having a coefficient of expansion that is from about 95% to about 105% of the coefficient of expansion of the glass.

10. The laminate system of claim 9 wherein the attachment means and/or the receptor means are metallic materials.

11. The laminate system of claim 10 wherein the laminate is useful as a floor tile, stair tread, glass wall, or ceiling tile.

12. A process for preparing a glazing system suitable for direct-point attachment to a support structure comprising the steps: assembling a laminate comprising (1) a thermoplastic interlayer; (2) at least one sheet of a rigid structural load-bearing layer (structural layer); (3) at least one receptor means; and (4) at least one attachment means, wherein the thermoplastic interlayer is bonded on at least one surface to at least one sheet of the structural layer, and wherein at least one receptor means is also adhesively bonded to the thermoplastic interlayer and thereby adhesively bonded to the structural layer, wherein the receptor means is positioned to mechanically accept the attachment means, with the further proviso that the attachment means and/or the receptor means are made from materials having a coefficient of expansion that is from about 90% to about 110% of the coefficient of expansion of the structural layer.

13. A process for fabricating a glass laminated glazing system that is suitable for a direct point attachment to a support structure via an attachment means and a receptor means comprising the step of choosing materials of construction for the laminate such that the attachment means and/or the receptor are made from materials having a coefficient of expansion that is from about 90% to about 110% of the coefficient of expansion of the glass.
